(19) United States
(12) Patent Application Publication
(10) Pub. No.: US 2026/0271253 A1
(43) Pub. Date: Sep. 10, 2026

(54) BRIDGE BOARD REMOVAL TOOL

(71) Applicant: NVIDIA Corp., Santa Clara, CA (US)

(72) Inventors: Aaron Poon, San Marino, CA (US); Yunzhe Zhao, San Jose, CA (US); Mirui Wang, Milpitas, CA (US)

(73) Assignee: NVIDIA Corp., Santa Clara, CA (US)

(21) Appl. No.: 19/071,574

(22) Filed: Mar. 5, 2025

(51) Int. Cl. H05K 13/00; B25B 27/14

(52) U.S. Cl. CPC H05K 13/0007; B25B 27/14

(57) ABSTRACT

Apparatus including a body formed with a pivot surface and multiple lever arms arranged along the pivot surface, each lever arm formed such that the body forms an acute angle of engagement with a chassis when the pivot surface contacts the chassis and a distal end of the lever arms contacts an underside of a board mounted parallel to the chassis and an arc of the lever arms contacts an edge of the board.

### BACKGROUND

Complicated integrated circuits such as central processing units and graphics processing units may be configured into chassis and rack systems (e.g., in enterprise server rooms and data centers) from which they interoperate for cooperative computing tasks such as artificial intelligence training and inference. These components may be organized within a chassis into circuit boards, and the circuit boards may be communicatively coupled to one another using bridge boards.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts an exemplary server system in accordance with one embodiment.

FIG. 2 depicts an exemplary processing system in accordance with another embodiment.

FIG. 3 depicts a chassis comprising multiple circuit boards and a bridge board in accordance with one embodiment.

FIG. 4 is a side view depiction of a bridge board utilized on a chassis in accordance with one embodiment.

FIG. 5 depicts a top perspective view of a bridge removal tool in accordance with one embodiment.

FIG. 6 depicts a top perspective view of a bridge removal tool in accordance with another embodiment.

FIG. 7 depicts a bottom perspective view of a bridge removal tool in accordance with one embodiment.

FIG. 8 depicts a bottom perspective view of a bridge removal tool in accordance with another embodiment.

FIG. 9 depicts a side view example of an embodiment of a bridge removal tool in a first deployment arrangement.

FIG. 10 depicts a side view example of an embodiment of a bridge removal tool in a second deployment arrangement.

FIG. 11 depicts a side view example of an embodiment of a bridge removal tool in a third deployment arrangement.

FIG. 12 depicts an example of a human user operating an embodiment of a bridge removal tool.

FIG. 13 depicts an example of a dual deployment arrangement of a bridge removal tool in one aspect.

FIG. 14 depicts an example of a dual deployment arrangement of a bridge removal tool in another aspect.

FIG. 15A depicts a side view of a bridge removal tool in accordance with another embodiment.

FIG. 15B depicts a perspective view of a bridge removal tool in accordance with another embodiment.

FIG. 15C depicts a front view of a bridge removal tool in accordance with another embodiment.

FIG. 16 depicts an exemplary computer system in accordance with one embodiment.

FIG. 17 depicts a parallel processing unit in accordance with one embodiment.

### DETAILED DESCRIPTION

It can be difficult to remove a bridge board once it's installed between the boards in a chassis due minimal clearance and lack of grip on the bridge board. Due to its low-profile form factor, and lack of clearance from the chips or packages upon which it is mounted, and the high forces needed for removal, removing a bridge board, such as an NVLink (see below) bridge board, may become very difficult for personnel. Mishandling risk is high when applying excessive and uneven force to remove the bridge board, which may damage the connectors and edge board gold fingers causing connectivity and signal integrity issues. This disclosure relates to a removal tool to disengage a bridge board coupling two or more integrated circuit chips or packages. The removal tool includes a handle and levers assembled onto the handle, the levers configured to set an angle of engagement enabling disengagement of the bridge board connectors from board edge fingers, whereby urging the handle, the bridge board disengages from the chips or packages. The levers are placed between boards comprising the chips or packages, and underneath the bridge board. With a simple press on the handle, the bridge board may be disengaged from the chips or packages so that the user can easily remove it. The removal tool has utility for example when servicing chips or packages such as graphics processing units (GPUs) or replacing faulty components, ensuring the bridge board can be safely removed.

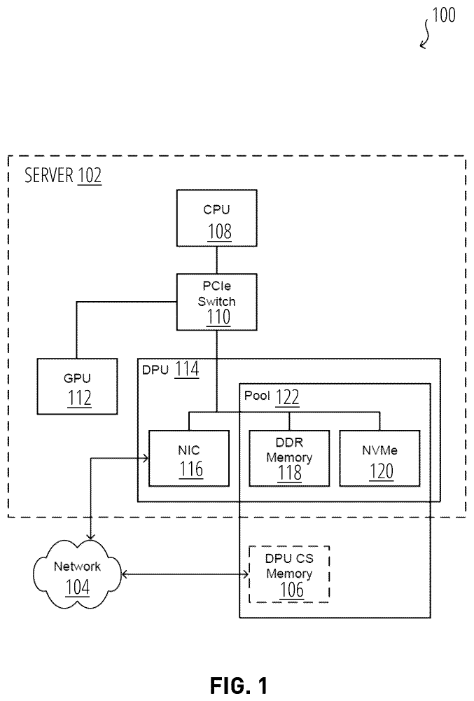

FIG. 1 depicts an example computing environment 100 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures.

The example computing environment 100 may include (one or more) server 102 which may be used to perform HPC workloads, such as AI training or machine learning model training. One or more of the servers may comprise a chassis and multiple processor boards coupled via a bridge board, as depicted and described more fully below. The removal of said bridge boards may utilize embodiments of the mechanisms disclosed herein. In an embodiment, the server 102 may be an application instance or a compute node. The server 102 may include a CPU 108 associated with a switch 110, such as a peripheral component interconnect express (PCIe) switch, which may control at least some data transmission over communication paths interconnecting various components. In an embodiment, the CPU 108 may include a root complex processor.

The PCIe switch 110 may also be associated with a GPU 112 and a DPU 114, and may transmit data between at least some of the CPU 108, the GPU 112, the DPU 114, and other components. In an embodiment, the PCIe switch 110 may be associated with more than one GPU or more than one DPU. In another embodiment, the PCIe switch 110 may be located within the DPU 114. The PCIe switch 110 may manage the transfer of at least some data between the CPU 108, the GPU 112, and the DPU 114. In another embodiment, the number of GPUs associated with the PCIe switch 110 may be equal to the number of DPUs associated with the PCIe switch 110. In at least one embodiment, the server 102 may include, without limitation, any number of the CPUs 108, the PCIe switches 110, the GPUs 112, and/or the DPUs 114, in any combination. For example, in at least one embodiment, server 102 could include eight, sixteen, thirty-two, and/or more GPUs 112.

In at least one embodiment, communication paths interconnecting various components, including but not limited to the CPU 108, the PCIe switch 110, the GPU 112, and the DPU 114, in FIG. 1 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 114 may include a network interface card (NIC) 116, a DDR memory 118, and a non-volatile memory express (NVMe) device 120. The NIC 116 may be able to interface with a network 104, which may also interface with additional NVMe devices available to the DPU 114, such as over fabric. In an embodiment, the DPU 114 may not include the NVMe device 120. In another embodiment, the NVMe device 120 may be located on the server 102 and not on the DPU 114.

In yet another embodiment, the computing environment 100 may include more than one of the NVMe device 120, such as a first NVMe device in the DPU 114 and a second NVMe device on the server 102 associated directly with the PCIe switch 110. In an embodiment, the DPU 114 may not include the DDR memory 118 and may include a computational storage services (CSS) in place of, or in addition to, the DDR memory 118. For example, computing environment 100 may include DPU computational storage (CS) memory 106 available to the DPU 114 as part of the CSS. The network 104 may be able to interface with the DPU CS memory 106 through the NIC 116, according to any suitable interface protocol, such as remote direct memory access (RDMA) over Ethernet, InfiniBand, Fiber Channel, etc..

The total memory of the computing environment 100 available for data storage may be expanded through the use of the DPU 114 on nodes of the system. The DPU 114 may have access to a pool 122 of memory already available to the server 102, such as double data rate (DDR) memory, on-board NVMe devices, NVMe devices over fabric, and CS. The pool 122 of memory may include at least one of the DDR memory 118, NVMe device 120, and the DPU CS memory 106.

The DPU 114 may also be able to access the available memory of other DPUs as part of the pool 122, and other DPUs may be able to access the available memory of DPU 114, such as the pool 122. This available memory can be accessed and utilized for data storage, without the addition of compute resources, such as compute nodes, which would be required using other solutions.

The available pool 122 accessible to the DPU 114 may be provisioned for the server 102 to expand the total memory available for data storage, such as to reduce the data storage load on the CPU 108 or the GPU 112, which can instead increase the utilization of their memory for processing. For example, during training of an AI, the model states, residual states, activation functions, and checkpoints can be stored, or offloaded, on the pool 122 accessible to the DPU 114.

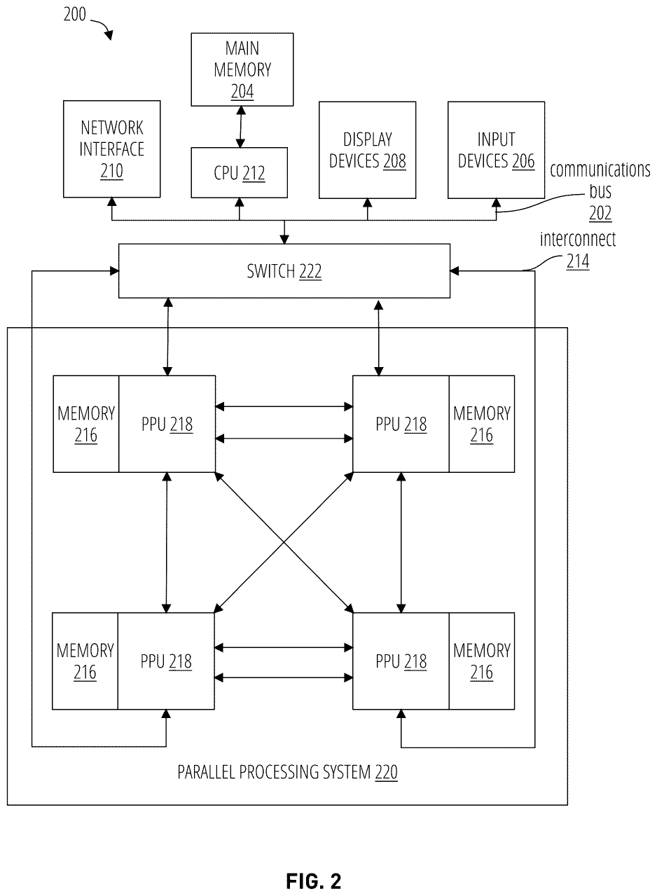

FIG. 2 depicts a computer system 200, according to at least one embodiment. In at least one embodiment, computer system 200 is configured with components such as multiple parallel processing units that utilize one or more bridge board. The removal of said bridge boards may utilize embodiments of the mechanisms disclosed herein.

In at least one embodiment, computer system 200 comprises, without limitation, at least one central processing unit (“CPU”) 212 that is connected to a communications bus 202 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 200 includes, without limitation, a main memory 204 and control logic (e.g., implemented as hardware, software, or a combination thereof) and data are stored in main memory 204 which may take form of random-access memory (“RAM”). In at least one embodiment, a network interface subsystem (“network interface”) 210 provides an interface to other computing devices and networks for receiving data from and transmitting data to other systems from computer system 200.

In at least one embodiment, computer system 200 includes, without limitation, input devices 206, parallel processing system 220, and display devices 208 which can be implemented using a conventional cathode ray tube (“CRT”), liquid crystal display (“LCD”), light emitting diode (“LED”), plasma display, or other suitable display technologies. In at least one embodiment, user input is received from input devices 206 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 204 and/or secondary storage. Computer programs, if executed by one or more processors, enable computer system 200 to perform various functions in accordance with at least one embodiment. Main memory 204, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 212; parallel processing system 220; an integrated circuit capable of at least a portion of capabilities of both CPU 212; parallel processing system 220; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 200 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 220 includes, without limitation, a plurality of parallel processing units (“PPUs”) 218 and associated memories 216. In at least one embodiment, PPUs 218 are connected to a host processor or other peripheral devices via an interconnect 214 and a switch 222 or multiplexer. In at least one embodiment, parallel processing system 220 distributes computational tasks across PPUs 218 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 218, although such shared memory may incur performance penalties relative to use of local memory and registers resident to a PPU 218. In at least one embodiment, operation of PPUs 218 is synchronized through use of a command such as_syncthreads (), wherein all threads in a block (e.g., executed across multiple PPUs 218 to reach a certain point of execution of code before proceeding.

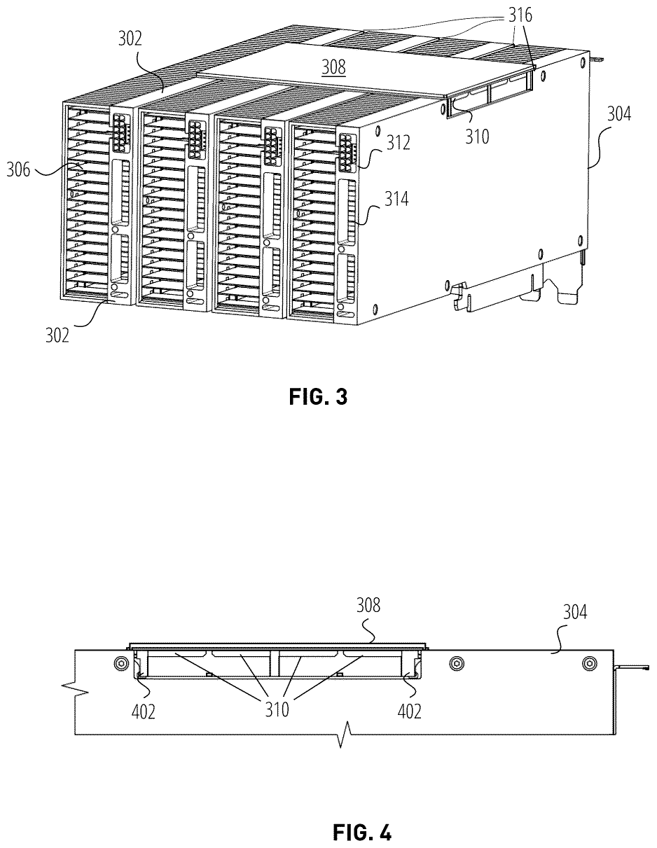

FIG. 3 depicts a chassis comprising multiple boards and a bridge board in accordance with one embodiment. The chassis may be utilized for example in systems in accordance with FIG. 1 and FIG. 2. Multiple boards 302 are configured into a chassis 304, and there may be multiple chassis 304 configured into a rack system, for example in a data center or enterprise server room. By way of example, the boards 302 may each comprise one or more graphics processing unit (GPU), central processing unit (CPU), and combinations thereof, and may include complementary circuitry and logic therefor such as power modules, temperature control logic, memory, and so on. In one example, the boards 302 may include central processing units (CPUs), graphics processing units (GPUs), data processing units (DPUs), quantum processing units (QPUs), a plurality of parallel processing units (PPUs), and application-specific integrated circuits (ASICs). QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

The depicted chassis 304 comprises a dual-slot configuration of four boards 302. In general, the chassis 304 may comprise any number of boards 302 in different sizes and configurations, such as single-slot boards, dual-slot boards, triple-slot boards, and combinations of boards of different sizes.

Each board 302 has associated cooling fins 306 to dissipate heat, vents 314, and power ports 312. The boards 302 are coupled via a bridge board 308 comprising connectors 310 aligned with input/output pins of the circuity on the boards 302. The bridge board may be any high-speed interconnect. Example host attachment technologies include compute express link (CXL) as part of PCI-5.0 spec, NVLink (used for GPUs), cache coherent interconnect for accelerators (CCIX) used for ARM processors, and OpenCAPI (open coherent accelerator processor interface). The bridge board 308 is mounted parallel to a surface of the chassis 304. In one embodiment, the bridge board 308 may comprise a number of connectors 310 for each board 302 equal to the number of boards 302 in the chassis 304 (e.g., four connectors per board 302 for the four-board configuration depicted, two connectors per board 302 for a two-board configuration, eight connectors per board 302 for an eight-board configuration). In a particular embodiment in which each board 302 comprises one graphics processing unit, each connector 310 may comprise 256 pins. The bridge board 308 may comprise logic such as metal paths, optical paths, and switching fabrics to enable signaling between the boards 302.

In the example depicted in FIG. 3, the bridge board 308 bridges all of the boards 302 in the chassis 304. In other embodiments, a particular bridge board 308 may bridge less than all of the boards 302 in the chassis 304. For example, a chassis 304 comprising four boards 302 may utilize two bridge boards 308, each bridging only two of the four boards 302.

A bridge removal tool may engage with gaps 316 in the chassis 304, including a gap at an edge of the bridge board 308 where it protrudes slightly beyond an extent of the chassis 304.

FIG. 4 is a side view depiction of a bridge board utilized on a chassis in accordance with one embodiment. FIG. 4 depicts the connectors 310 of the bridge board 308 in additional aspects, and also depicts retaining mechanisms 402 (e.g., clips or clamps) that may be utilized to stabilize the bridge board 308 in relation to the chassis 304.

In one embodiment, the connector 310 are configured to interface with pins of PCIe interfaces to circuity on the boards 302. PCIe, or Peripheral Component Interconnect Express, is a high-speed interface commonly utilized to connect various components and peripherals in computer systems. PCIe is commonly utilized for connecting graphics boards, solid-state disks, network cards, and other expansion boards to the system. PCIe comprises a point-to-point architecture, enabling direct data links between devices and a data processor for example, resulting in higher transfer rates compared to earlier interface standards.

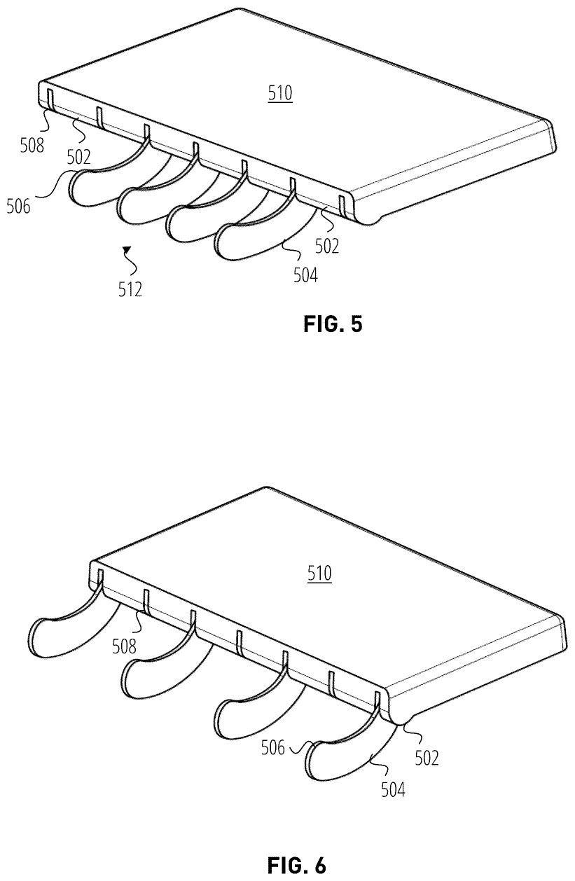

FIG. 5 depicts a top perspective view of a bridge removal tool in accordance with one embodiment. The bridge removal tool comprises a body 510 comprising multiple slots 508. A set of (e.g., four) adjacent slots 508 are configured with lever arms 512 each comprising an arc or hook 504 and a distal end 506 (distal from the body 510/slots 508). The lever arms 512 may be formed for example from metal or extruded or molded plastic, although plastic may be preferred as being less likely to damage the bridge board 308 during removal. The body 510 may also for example be formed from (extruded or molded) plastic, or metal. The body 310 serves as a handle for operating the bridge removal tool.

The body 510 may comprise more slots 508 than lever arms 512, so that the bridge removal tool may be reconfigured with lever arms 512 in different positions and/or with different numbers of lever arms 512. Herein, ‘adjacent slots’ refers to two slots that are not separated from one another by one or more intervening slot.

The body 510 is further formed with a pivot surface 502. The body 510, pivot surface 502, and lever arms 512 may be cooperatively utilized to disengage a bridge board 308 from multiple boards 302 in manners described below. The configuration of the bridge removal tool depicted in FIG. 5 may be utilized with a single-slot configuration of multiple boards 302. The number of lever arms 512 and their slot locations may be configured to suit a particular configuration of boards 302 and board sizes in a given chassis 304.

FIG. 6 depicts a top perspective view of a bridge removal tool in accordance with another embodiment. The configuration of the bridge removal tool depicted in FIG. 6 may be utilized with a dual-slot configuration of multiple boards 302 (hence the additional spacing between the lever arms 512). In this configuration the lever arms 512 are mounted in alternate slots 508, meaning that there is one empty slot separating the slots with lever arms mounted in them. A dual-slot configuration may accommodate up to 88 boards, doubling the number of available GPUs compared to the single-slot configuration.

As with the single-slot configuration depicted in FIG. 5, the number of lever arms 512 and their slot locations may be configured to suit a particular configuration of boards 302 and board sizes in a given chassis 304. For example, the lever arms 512 of the bridge removal tool may be configured to remove a bridge board 308 from a chassis 304 comprising a non-uniform arrangement of bridged single-slot and dual-slot boards 302.

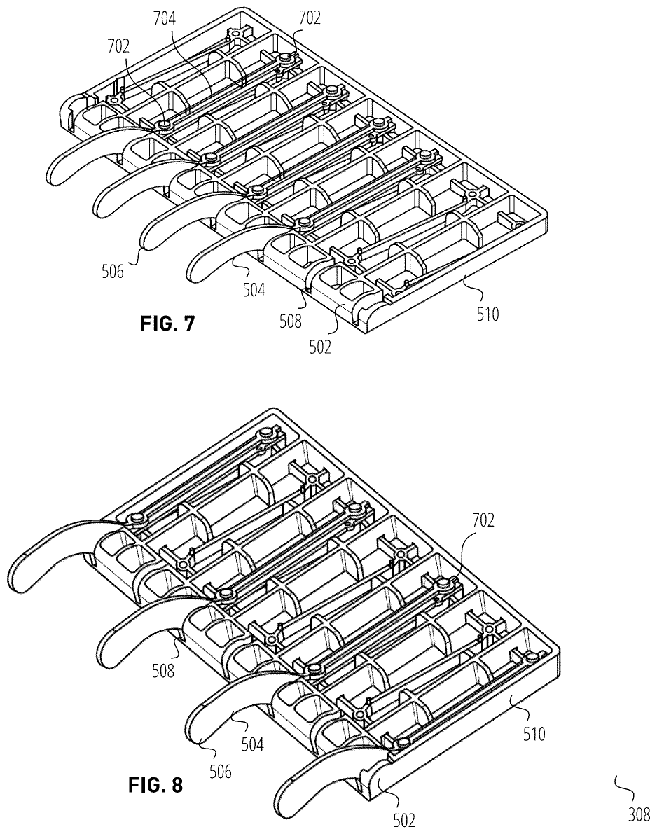

FIG. 7 depicts a bottom perspective view of a bridge removal tool in accordance with the single-slot compatible embodiment depicted in FIG. 5. The bridge removal tool is highly configurable for different bridging configurations. A lever arm 312 may be added to or removed from any slot 508 via the installation or removal of a rigid coupler 704 (e.g., a plastic or metal rod) secured with common retaining mechanisms 702 such as screws, bolts, or pins. In one embodiment, the lever arms 512 and the rigid coupler 704 are formed as a single piece of molded (e.g., extruded) heavy-duty plastic.

FIG. 8 depicts a bottom perspective view of a bridge removal tool in accordance with the dual-slot compatible embodiment depicted in FIG. 6.

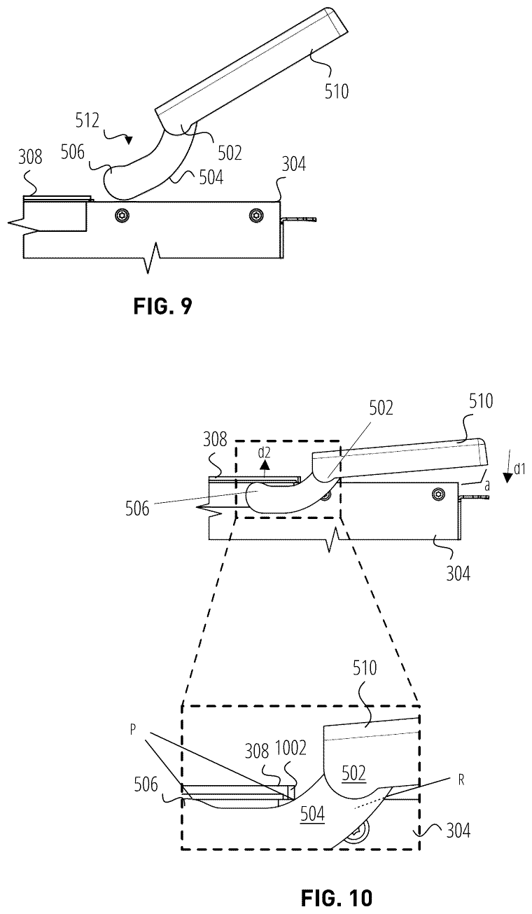

FIG. 9 depicts a side view of an embodiment of a bridge removal tool in a first deployed arrangement. Only one of the lever arms 512 is depicted, this being the lever arm 512 that engages with a gap at an edge of the bridge board 308 where it protrudes slightly beyond an extent of the chassis 304.

FIG. 10 depicts a view of the bridge removal tool of FIG. 9 in a second deployed arrangement. The points P indicate points of contact between the lever arm 512 and the bridge board 308. Contact is made between the distal end 506 of the lever arm 512 and the bridge board 308, and between an edge of the bridge board 308 and a point along the arc 504 of the lever arm 512. The pivot surface 502 of the body 510 also contacts the chassis 304 (at a point R behind the one depicted lever arm 512), acting as a fulcrum.

In the deployed arrangement of FIG. 10, the body 510 is at an angle a with the top surface of the chassis 304. This angle may for example be between 5 and 30 degrees. From this angle of engagement, the body 510 may be urged along an approximate vector d1, with components both toward the chassis 304 and toward the bridge board 308. Urging the body 510 along vector d1 may instill a force on the bridge board 308 along vector d2, away from the chassis 304. The urging of the bridge board 308 along vector d2 is facilitated by engagement of the radius of the arc/hook 504 with the edge of the bridge board 308. This latter engagement facilitates initial unlatching of the connectors on the bridge board 308 from gold fingers of the underlying chip or package, and helps prevent damage to the bridge board 308, connectors 310, or underlying chips or packages during removal of the bridge board 308.

The bridge removal tool may thus comprise lever arms 512 arranged linearly along the pivot surface 502 of the body 510, each lever arm 512 comprising an arc 504 and a distal end 506. The lever arms 512 are inserted into gaps 316 in the chassis 304 at the edge 1002 of the bridge board 308, and the arcs 504 of the lever arms 512 are formed such that the body 510 of the bridge removal tool forms a shallow angle (between five and thirty degrees) with the chassis 304 when the pivot surface 502 contacts the chassis 304, and the distal ends 506 of the lever arms 512 contact an underside of the bridge board 308, and the arcs 504 contact the edge 1002 of the bridge board 308. Herein, the ‘underside’ surface of the bridge board 308 refers to the surface of the bridge board 308 adjacent to the surface of the chassis 304. The angle may be configured just sufficiently to disengage the connectors 310 of the bridge board 308 from the edge gold fingers of the boards 302. With a simple rotational force applied at the pivot surface, the bridge board 308 may disengage from the underlying chips or packages so that the user can easily remove it.

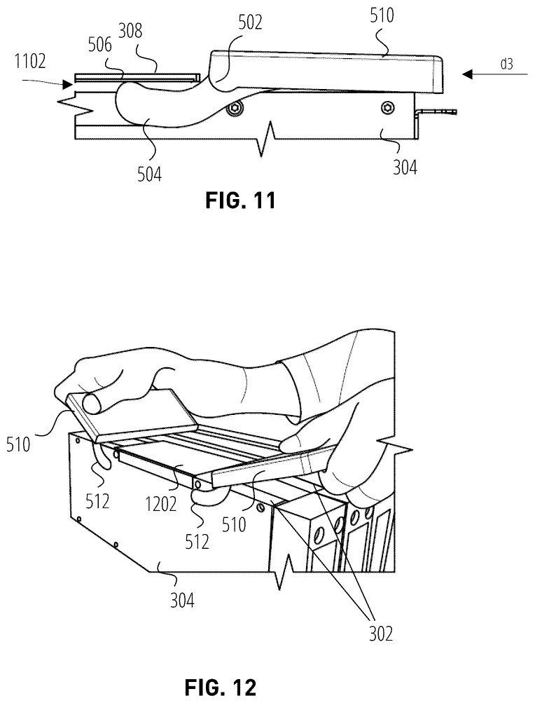

FIG. 11 depicts an example of an embodiment of a bridge removal tool in a third deployed arrangement. The body 510 has been urged into contact with the chassis 304 and toward the bridge board 308 along vector d3, disengaging the connectors 310 of the bridge board 308 from the corresponding ports (e.g., PCIe) on the boards 302 and forming a separation 1102 between the bridge board 308 and the chassis 304.

FIG. 12 depicts an example of a human user operating an embodiment of a bridge removal tool. Unlike the bridge board 308 depicted in prior drawings, the bridge board 1202 depicted in FIG. 12 spans and bridges two boards in the chassis 304, not four.

To remove the bridge board 1202, the human user employs a pair of bridge removal tool, one in each hand. The lever arms 512 of the bridge removal tool are engaged with the bridge board 1202 at both ends and operated as described in conjunction with FIG. 9-FIG. 11 to create a separation 1102 between the bridge board 1202 and the chassis 304. Once the separation 1102 is established, the human user may use their hands to complete the removal of the bridge board 1202 from the boards 302. The tool may be pressed downward and toward the board until bottoms-up to the underlying connector.

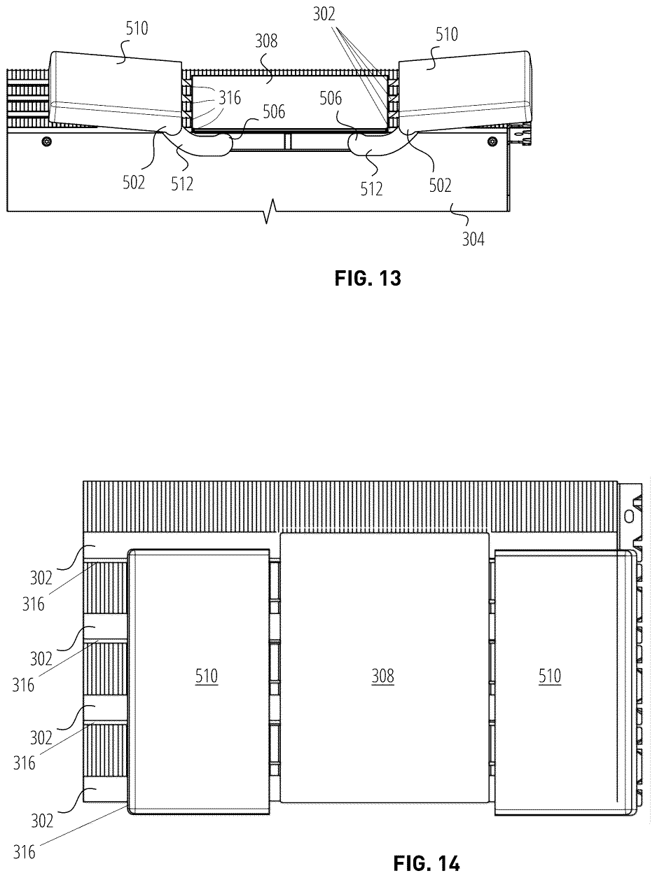

FIG. 13 and FIG. 14 depict an example of a dual deployment of a bridge removal tool in one aspect. A bridge removal tool is deployed on each of two sides of the bridge board 308 in the initial configuration depicted in FIG. 9. The lever arms 512 are inserted into slots gaps 316 along the boards 302 and the distal ends 506 of the lever arms 512 are engaged with the underside of the bridge board 308. The body 510 of the bridge removal tool is angled (e.g., 5 to 30 degrees) in relation to the chassis 304.

The dual deployment configuration may not be required for removing the bridge board in every circumstance. However, the dual deployment configuration may be advantageous over use of a single bridge removal tool because it may lessen the chances of damaging the bridge board and/or the connectors on the boards.

Once deployed in the initial configuration of FIG. 9, both bridge removal tool may each be operated together as described in conjunction with FIG. 10 and FIG. 11 to create the separation 1102 at both ends of the bridge board 308.

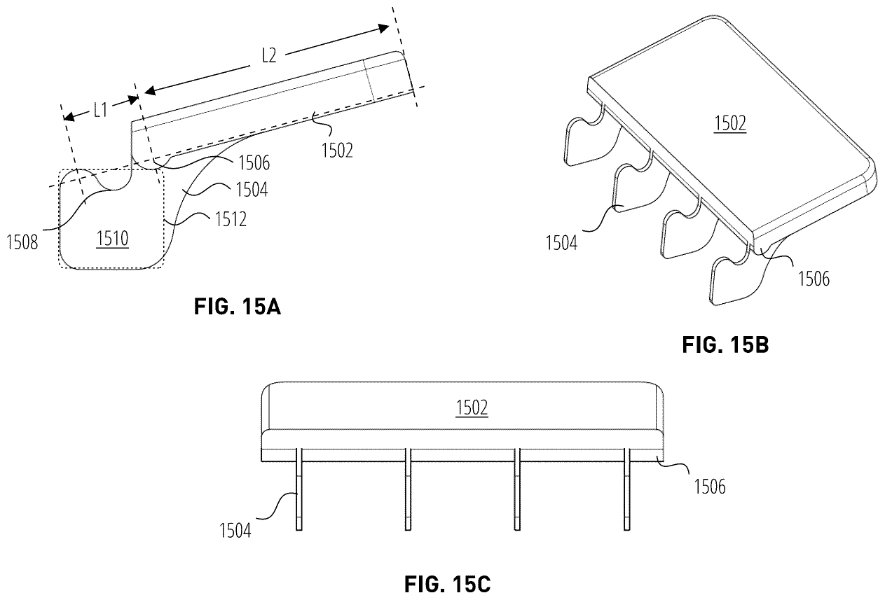

FIG. 15A-FIG. 15C depict a side, perspective, and front view of a bridge removal tool in accordance with another embodiment. This embodiment may be formed as a single piece, e.g., as molded or extruded plastic, obviating the need for assembling parts together. This embodiment may be operated to disengage a bridge board from boards 302 in a chassis 304 using the process depicted in FIG. 9-FIG. 14.

The bridge removal tool comprises a body 1502 with an integral pivot surface 1506, and a plurality of lever arms 1504 each with a distal end 1510 comprising a rectangular bulk shape 1512 with a depression/valley 1508 formed in it. The lever arms 1504 and the body 1502 may be molded as a single piece. Depending on the configuration of the circuit boards in the chassis system, the bridge removal tool may be formed to have different numbers of the lever arms 1504 in different configurations, as previous described in conjunction with other embodiments. To provide sufficient levering force, the L2 extent of the body 1502 from the pivot surface 1506 (depicted in FIG. 15A) may be proportioned at least twice the L1 extent of the rectangular bulk shape 1512 from the pivot surface 1506.

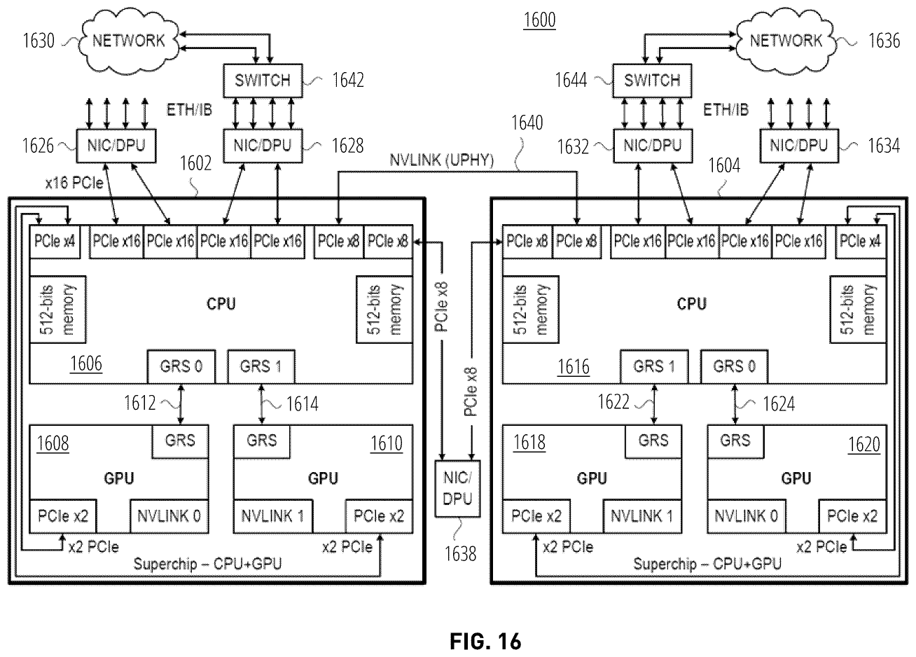

FIG. 16 depicts a block diagram that schematically illustrates a computing system 1600, e.g., a data center or a High-Performance Computing (HPC) cluster, in accordance with an embodiment that is described herein. The computing system 1600 comprises a plurality of subsystems, e.g. multiple processing devices coupled to each other, multiple network devices, and multiple networks, according to at least one embodiment. Computing system 1600 is designed with multiple integrated circuits (referred to as processing devices), where each integrated circuit can include one or more CPUs and GPUs, forming a powerful and flexible architecture. In some configurations, the sub-systems and/or the CPUs/GPUs of computing system 1600 may be implemented on circuit boards coupled via one or more bridge boards. The removal of said bridge boards may utilize embodiments of the mechanisms disclosed herein.

The various processing devices are interconnected via an NVLink or other high-speed interconnect, enabling high-speed communication between the subsystems, and are also connected through a NIC or DPU (Data Processing Unit) to ensure efficient data transfer across computing system 1600 and to one or more external networks 1630, 1636. In the present example, system 1600 comprises a packet switch 1642 that connects NIC/DPU 1628 to network 1630, and a packet switch 1644 that connects NIC/DPU 1632 to network 1636.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs.

FIG. 16 also depicts an example of a multi-GPU architecture. As depicted, computing system 1600 includes a processing device 1602 with a multi-GPU architecture. In particular, processing device 1602 may be a system-on-chip that includes multiple subsystems such as a CPU 1606, a GPU 1608, and a GPU 1610. CPU 1606 can be coupled to GPU 1608 via a die-to-die (D2D) or chip-to-chip (C2C) interconnect 1612, such as a Ground-Referenced Signaling interconnect (GRS interconnect). CPU 1606 can be coupled to GPU 1610 via a D2D or C2C interconnect 1614. CPU 1606 can also couple to GPU 1608 and GPU 1610 via PCIe interconnects.

CPU 1606 can be coupled to one or more NICs or DPUs, which are coupled to one or more networks. For example, as depicted in FIG. 16, CPU 1606 is coupled to a first NIC/DPU 1626, which is coupled to a network 1630. CPU 1606 is also coupled to a second NIC/DPU 1628, which is coupled to network 1630 via switch 1642. NIC/DPU 1626 and NIC/DPU 1628 can be coupled to network 1630 over Ethernet (ETH), NVLINK or InfiniBand (IB) connections, for example.

Computing system 1600 also includes a processing device 1604 with a multi-GPU architecture. In particular, processing device 1604 includes multiple subsystems including a CPU 1616, a GPU 1618, and a GPU 1620. CPU 1616 can be coupled to GPU 1618 via an D2D or C2C interconnect 1622. CPU 1616 can be coupled to GPU 1620 via a D2D or C2C interconnect 1624. CPU 1616 can also couple to GPU 1618 and GPU 1620 via PCIe interconnects. CPU 1616 can be coupled to one or more NICs or DPUs, which are coupled to one or more networks. For example, as illustrated in FIG. 16, CPU 1616 is coupled to a first NIC/DPU 1632, which is coupled to a network 1636. CPU 1616 is also coupled to a second NIC/DPU 1634, which is coupled to network 1636 via switch 1644. NIC/DPU 1632 and NIC/DPU 1634 can be coupled to network 1636 over Ethernet (ETH), NVLINK or InfiniBand (IB) connections.

In at least one embodiment, processing device 1602 and processing device 1604 may communicate with each other via a NIC/DPU 1638, such as over PCIe interconnects. Processing device 1602 and processing device 1604 may also communicate with each other over a high-bandwidth communication interconnects 1640, such as an NVLink interconnect or other high-speed interconnects. The packet switches in FIG. 16 may comprise, for example, Nvidia Quantum-2 switches. The NICs/DPUs in the figure may comprise, for example, Nvidia Bluefield DPUs.

Computing devices utilizing one or more graphic processing unit (GPU) and/or general purpose data processor (e.g., a ’central processing unit or CPU) may be configured with bridge boards, the removal of which may utilize embodiments of the mechanisms disclosed herein. Exemplary architectures will now be described that may be configured to implement the mechanisms disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

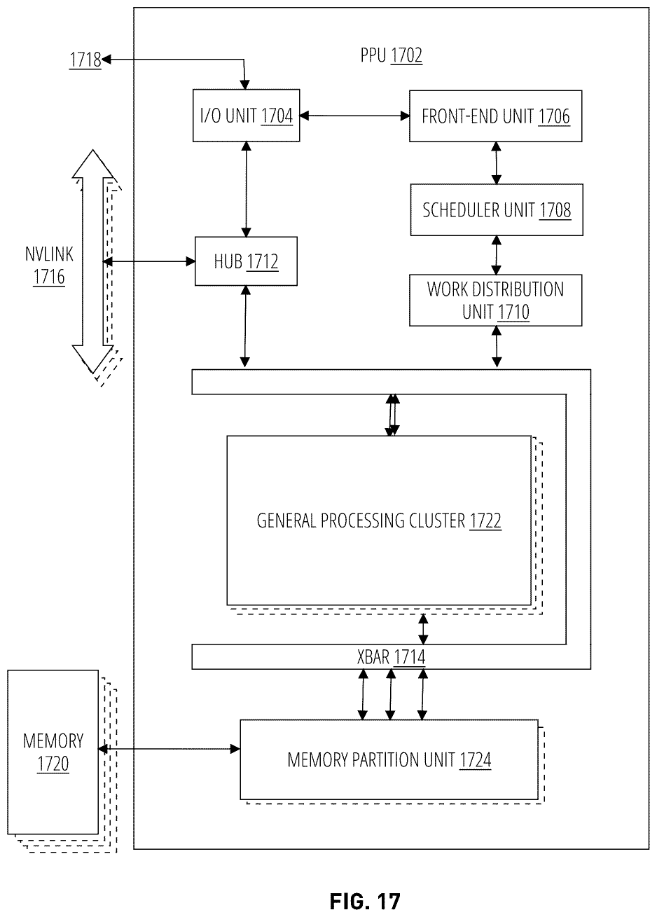

FIG. 17 depicts a parallel processing unit 1702, in accordance with an embodiment. In an embodiment, the parallel processing unit 1702 is a multi-threaded processor that is implemented on one or more integrated circuit devices. The parallel processing unit 1702 is a latency hiding architecture designed to process many threads in parallel. A thread (e.g., a thread of execution) is an instantiation of a set of instructions configured to be executed by the parallel processing unit 1702. In an embodiment, the parallel processing unit 1702 is a graphics processing unit (GPU) configured to implement a graphics rendering pipeline for processing three-dimensional (3D) graphics data in order to generate two-dimensional (2D) image data for display on a display device such as a liquid crystal display (LCD) device, an organic light emitting diode (OLED) device, a transparent light emitting diode (TOLED) device, a field emission display (FEDs), a field sequential display, a projection display, a head mounted display or any other desired display. In other embodiments, the parallel processing unit 1702 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

For example, one or more parallel processing unit 1702 modules may be configured to accelerate thousands of High Performance Computing (HPC), data center, and machine learning applications. The parallel processing unit 1702 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

The parallel processing unit 1702 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 1702 is embodied on a single semiconductor substrate. In another embodiment, the parallel processing unit 1702 is included in a system-on-a-chip (SoC) along with one or more other devices such as additional parallel processing units 1702, the memory 1720, a reduced instruction set computer (RISC) CPU, a memory management unit (MMU), a digital-to-analog converter (DAC), and the like.

In an embodiment, the parallel processing unit 1702 may be included on a graphics board that includes one or more memory devices 1720. The graphics board may be configured to interface with a PCIe slot on a motherboard of a desktop computer. In yet another embodiment, the parallel processing unit 1702 may be an integrated graphics processing unit (iGPU) or parallel processor included in the chipset of the motherboard.

As shown in FIG. 17, the parallel processing unit 1702 includes an I/O unit 1704, a front-end unit 1706, a scheduler unit 1708, a work distribution unit 1710, a hub 1712, a crossbar 1714, one or more general processing clusters 1722, and one or more memory partition units 1724. The parallel processing unit 1702 may be connected to a host processor or other parallel processing unit 1702 modules via one or more high-speed NVLink 1716 interconnects. The parallel processing unit 1702 may be connected to a host processor or other peripheral devices via an interconnect 1718. The parallel processing unit 1702 may also be connected to a local memory comprising a number of memory 1720 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 1720 may comprise logic to configure the parallel processing unit 1702 to carry out aspects of the techniques disclosed herein.

The NVLink 1716 interconnect enables systems to scale and include one or more parallel processing unit 1702 modules combined with one or more CPUs, supports cache coherence between the parallel processing unit 1702 modules and CPUs, and CPU mastering. Data and/or commands may be transmitted by the NVLink 1716 through the hub 1712 to/from other units of the parallel processing unit 1702 such as one or more copy engines, a video encoder, a video decoder, a power management unit, etc. (not explicitly shown).

The I/O unit 1704 is configured to transmit and receive communications (e.g., commands, data, etc.) from a host processor (not shown) over the interconnect 1718. The I/O unit 1704 may communicate with the host processor directly via the interconnect 1718 or through one or more intermediate devices such as a memory bridge. In an embodiment, the I/O unit 1704 may communicate with one or more other processors, such as one or more parallel processing unit 1702 modules via the interconnect 1718. In an embodiment, the I/O unit 1704 implements a Peripheral Component Interconnect Express (PCIe) interface for communications over a PCIe bus and the interconnect 1718 is a PCIe bus. In alternative embodiments, the I/O unit 1704 may implement other types of well-known interfaces for communicating with external devices.

The I/O unit 1704 decodes packets received via the interconnect 1718. In an embodiment, the packets represent commands configured to cause the parallel processing unit 1702 to perform various operations. The I/O unit 1704 transmits the decoded commands to various other units of the parallel processing unit 1702 as the commands may specify. For example, some commands may be transmitted to the front-end unit 1706. Other commands may be transmitted to the hub 1712 or other units of the parallel processing unit 1702 such as one or more copy engines, a video encoder, a video decoder, a power management unit, etc. (not explicitly shown). In other words, the I/O unit 1704 is configured to route communications between and among the various logical units of the parallel processing unit 1702.

In an embodiment, a program executed by the host processor encodes a command stream in a buffer that provides workloads to the parallel processing unit 1702 for processing. A workload may comprise several instructions and data to be processed by those instructions. The buffer is a region in a memory that is accessible (e.g., read/write) by both the host processor and the parallel processing unit 1702. For example, the I/O unit 1704 may be configured to access the buffer in a system memory connected to the interconnect 1718 via memory requests transmitted over the interconnect 1718. In an embodiment, the host processor writes the command stream to the buffer and then transmits a pointer to the start of the command stream to the parallel processing unit 1702. The front-end unit 1706 receives pointers to one or more command streams. The front-end unit 1706 manages the one or more streams, reading commands from the streams and forwarding commands to the various units of the parallel processing unit 1702.

The front-end unit 1706 is coupled to a scheduler unit 1708 that configures the various general processing clusters 1722 to process tasks defined by the one or more streams. The scheduler unit 1708 is configured to track state information related to the various tasks managed by the scheduler unit 1708. The state may indicate which general processing cluster 1722 a task is assigned to, whether the task is active or inactive, a priority level associated with the task, and so forth. The scheduler unit 1708 manages the execution of a plurality of tasks on the one or more general processing clusters 1722.

The scheduler unit 1708 is coupled to a work distribution unit 1710 that is configured to dispatch tasks for execution on the general processing clusters 1722s. The work distribution unit 1710 may track a number of scheduled tasks received from the scheduler unit 1708. In an embodiment, the work distribution unit 1710 manages a pending task pool and an active task pool for each of the general processing clusters 1722. The pending task pool may comprise a number of slots (e.g., 32 slots) that contain tasks assigned to be processed by a particular general processing cluster 1722. The active task pool may comprise a number of slots (e.g., 4 slots) for tasks that are actively being processed by the general processing clusters 1722s. As a general processing cluster 1722 finishes the execution of a task, that task is evicted from the active task pool for the general processing cluster 1722 and one of the other tasks from the pending task pool is selected and scheduled for execution on the general processing cluster 1722. If an active task has been idle on the general processing cluster 1722, such as while waiting for a data dependency to be resolved, then the active task may be evicted from the general processing cluster 1722 and returned to the pending task pool while another task in the pending task pool is selected and scheduled for execution on the general processing cluster 1722.

The work distribution unit 1710 communicates with the one or more general processing clusters 1722 via crossbar 1714. The crossbar 1714 is an interconnect network that couples many of the units of the parallel processing unit 1702 to other units of the parallel processing unit 1702. For example, the crossbar 1714 may be configured to couple the work distribution unit 1710 to a particular general processing cluster 1722. Although not shown explicitly, one or more other units of the parallel processing unit 1702 may also be connected to the crossbar 1714 via the hub 1712.

The tasks are managed by the scheduler unit 1708 and dispatched to a general processing cluster 1722 by the work distribution unit 1710. The general processing cluster 1722 is configured to process the task and generate results. The results may be consumed by other tasks within the general processing cluster 1722, routed to a different general processing cluster 1722 via the crossbar 1714, or stored in the memory 1720. The results can be written to the memory 1720 via the memory partition unit 1724 modules, which implement a memory interface for reading and writing data to/from the memory 1720. The results can be transmitted to another parallel processing unit 1702 or CPU via the NVLink 1716. In an embodiment, the parallel processing unit 1702 includes a number U of memory partition unit 1724 modules that is equal to the number of separate and distinct memory 1720 devices coupled to the parallel processing unit 1702.

In an embodiment, a host processor executes a driver kernel that implements an application programming interface (API) that enables one or more applications executing on the host processor to schedule operations for execution on the parallel processing unit 1702. In an embodiment, multiple compute applications are simultaneously executed by the parallel processing unit 1702 and the parallel processing unit 1702 provides isolation, quality of service (QoS), and independent address spaces for the multiple compute applications. An application may generate instructions (e.g., API calls) that cause the driver kernel to generate one or more tasks for execution by the parallel processing unit 1702. The driver kernel outputs tasks to one or more streams being processed by the parallel processing unit 1702. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory.

### LISTING OF DRAWING ELEMENTS

100 computing environment
102 server
104 network
106 memory
108 CPU
110 switch
112 GPU
114 DPU
116 NIC
118 DDR memory
120 NVMe device
122 pool
200 computer system
202 communications bus
204 main memory
206 input devices
208 display devices
210 network interface
212 CPU
214 interconnect
216 memory
218 parallel processing unit
220 parallel processing system
222 switch
302 board
304 chassis
306 cooling fins
308 bridge board
310 connector
312 power port
314 vent
316 gap
402 retaining mechanism
502 pivot surface
504 arc
506 distal end
508 slot
510 body
512 lever arm
702 retaining mechanism
704 rigid coupler
1002 edge
1102 separation
1202 bridge board
1502 body
1504 lever arm
1506 pivot surface
1508 valley
1510 distal end
1512 rectangular bulk shape
1600 computing system
1602 processing device
1604 processing device
1606 CPU
1608 GPU
1610 GPU
1612 interconnect
1614 interconnect
1616 CPU
1618 GPU
1620 GPU
1622 interconnect
1624 interconnect
1626 NIC/DPU
1628 NIC/DPU
1630 network
1632 NIC/DPU
1634 NIC/DPU
1636 network
1638 NIC/DPU
1640 interconnect
1642 switch
1644 switch
1702 parallel processing unit
1704 I/O unit
1706 front-end unit
1708 scheduler unit
1710 work distribution unit
1712 hub
1714 crossbar
1716 NVLink
1718 interconnect
1720 memory
1722 general processing cluster
1724 memory partition unit

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S. C § 112(f).

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. An apparatus comprising:
a body comprising a pivot surface;
a plurality of lever arms arranged linearly along the pivot surface; and
each lever arm formed such that the body forms an acute angle of engagement with a circuit board.

2. The apparatus of claim 1, formed such that the body forms the acute angle of engagement with the circuit board in a configuration in which (a) the pivot surface contacts the circuit board, and (b) a distal end of the lever arms contacts an underside of a bridge board mounted parallel to the circuit board, and (c) an arc of the lever arms contacts an edge of the bridge board.

3. The apparatus of claim 1, consisting of four lever arms.

4. The apparatus of claim 1, consisting of two lever arms.

5. The apparatus of claim 1, wherein the bridge board spans a plurality of integrated circuit boards mounted in a chassis.

6. The apparatus of claim 5, wherein the integrated circuits comprise graphics processing units.

7. The apparatus of claim 5, wherein the integrated circuits comprise central processing units.

8. The apparatus of claim 1, wherein the body and the lever arms are formed from extruded plastic.

9. The apparatus of claim 8, wherein each lever arm comprises a distal end comprising a rectangular bulk shape with a valley formed in it.

10. The apparatus of claim 1, wherein the lever arms extend from slots formed in the pivot surface.

11. The apparatus of claim 10, wherein the body comprises more slots than lever arms.

12. The apparatus of claim 11, wherein a number and positions of the lever arms are reconfigurable among the slots.

13. The apparatus of claim 1, wherein the lever arms are retained in the body with screws, pins, or bolts.

14. A bridge board removal tool comprising:
a body comprising a pivot surface;
a plurality of lever arms arranged in adjacent slots formed in the pivot surface; and
each lever arm formed such that the body forms an acute angle of engagement with a circuit board.

15. The bridge board removal tool of claim 14, formed such that the body forms the acute angle of engagement with the circuit board in a configuration in which (a) the pivot surface contacts the circuit board, and (b) a distal end of the lever arms contacts an underside of the bridge board, and (c) an arc of the lever arms contacts an edge of the bridge board.

16. The bridge board removal tool of claim 14, wherein the body is formed such that a number of the lever arms is configurable.

17. An apparatus comprising:
a body comprising a pivot surface;
a plurality of lever arms mounted in alternate slots along the pivot surface; and
each lever arm formed such that the body forms an acute angle of engagement with a plurality of circuit boards.

18. The apparatus of claim 17, formed such that the body forms the acute angle of engagement with the circuit boards in a configuration in which (a) the pivot surface contacts the circuit boards, and (b) a distal end of the lever arms contacts an underside of a bridge board mounted perpendicular to the circuit boards, and (c) an arc of the lever arms contacts an edge of the bridge board.

19. The apparatus of claim 17, consisting of four lever arms.

20. A bridge board removal process, comprising:
(a) pivotably engaging a tool body at an acute angle with a plurality of circuit boards;
(b) inserting a plurality of lever arms into slots accessing an underside of the bridge board;
(c) contacting a distal end of the lever arms with the underside of the bridge board; and
(d) contacting a point along an arc of the lever arms with an edge of the bridge board.

21. The bridge board removal process of claim 20, further comprising:
with a first hand, performing actions (a)-(d) with a first tool on a first side of the bridge board; and
with a second hand, performing actions (a)-(d) with a second tool on a first side of the bridge board.

22. The bridge board removal process of claim 21, further comprising:
simultaneously urging the body of the first tool and the body of the second tool toward the circuit boards to form a gap between the bridge board and the circuit boards.

23. The bridge board removal process of claim 22, further comprising:
disengaging the bridge board from the circuit boards by lifting with the first hand and the second hand.

24. The bridge board removal process of claim 20, wherein the bridge board is mounted on a chassis in a data center or in an enterprise server room.

25. An apparatus comprising:
a body comprising a pivot surface;
a plurality of lever arms arranged linearly along the pivot surface;
the body and the lever arms formed as a single molded unit;
each lever arm formed such that the body forms an acute angle of engagement with a circuit board; and
each lever arm comprising a distal end comprising a rectangular bulk shape with a valley formed in it.
